(19) United States
(12) Patent Application Publication
(10) Pub. No.: US 2013/0242220 A1
(43) Pub. Date: Sep. 19, 2013

(54) THIN-FILM TRANSISTOR, METHOD OF MANUFACTURING THE SAME AND ACTIVE MATRIX DISPLAY PANEL USING THE SAME

(71) Applicants: WINTEK (CHINA) TECHNOLOGY LTD., Dongguan City (CN); WINTEK CORPORATION, Taichung City (TW)

(72) Inventors: Hui-Yu Chang, Changhua County (TW); Ming-Chang Yu, Taichung City (TW); Hsi-Rong Han, Taichung City (TW); Wen-Chun Wang, Taichung City (TW)

(73) Assignees: WINTEK CORPORATION, Taichung City (TW); WINTEK (CHINA) TECHNOLOGY LTD., Dongguan City (CN)

(21) Appl. No.: 13/794,749

(22) Filed: Mar. 11, 2013

(30) Foreign Application Priority Data
Mar. 15, 2012 (TW) 101108833

(51) Int. Cl. H01L 29/786; H01L 29/66; G02F 1/1368

(52) U.S. Cl. CPC H01L 29/7869; G02F 1/1368; H01L 29/66969
USPC 349/43; 257/43; 438/104

(57) ABSTRACT

The present invention provides a thin-film transistor disposed on a substrate. The thin-film transistor includes a gate, a first insulating layer, a metal-oxide semiconductor pattern, a source, a drain, and a second insulating layer. The gate is disposed on the substrate, and the first insulating layer covers the gate. The source and the drain are disposed on the first insulating layer. The metal-oxide semiconductor pattern is disposed on the substrate, and the second insulating layer covers the metal-oxide semiconductor pattern.

### BACKGROUND OF THE INVENTION

1. Field of the Invention

The present invention relates to a thin-film transistor, a method of manufacturing the same and an active matrix display panel using the same, and more particularly, to a thin-film transistor using an insulating layer as a protection layer, a method of manufacturing the same and an active matrix display panel using the same

2. Description of the Prior Art

Thin-film transistor serving as an active device has been widely applied to an active matrix display panel for driving liquid crystal molecules or an organic electroluminescent light-emitting diode. Since the oxide semiconductor thin-film transistor has high carrier mobility as a low temperature polysilicon thin film transistor and high uniformity of electricity as amorphous thin-film transistor, the display panel using the oxide semiconductor thin-film transistor has been an objective to be developed in this field.

In the conventional method of manufacturing the oxide semiconductor thin film transistor, a gate is formed on a substrate first, and then, a gate insulting layer covers the gate and the substrate. Next, a metal-oxide semiconductor layer is formed on the gate insulating layer, and a source and a drain are formed on the metal-oxide semiconductor layer. However, a material of the conventional metal-oxide semiconductor layer uses indium gallium zinc oxide (IGZO) that is sensitive to vapor and oxygen. For this reason, IGZO is easily reacted with both of vapor and oxygen, so that the electricity of IGZO will be changed. In addition, since the source and the drain are formed by etching a same metal layer, a surface of the IGZO is also easily damaged by an etching solution for etching metal layer or plasma of dry etching process, and even plasma for forming the protection layer also damages the surface of IGZO so as to change the electricity of the thin-film transistor. Furthermore, the IGZO also easily generates photo current, which is resulted from illuminate the IGZO by ultraviolet light, so that the electricity of the conventional oxide semiconductor thin-film transistor is bad and unstable.

As a result, to avoid bad electricity of the oxide semiconductor thin-film transistor resulted from the IGZO encountering vapor, oxygen, etching solution, and the ultraviolet light is an objective in this field.

### SUMMARY OF THE INVENTION

It is therefore an objective of the present invention to provide a thin-film transistor, a method of manufacturing the thin-film transistor and an active matrix display panel using the thin-film transistor to avoid bad electricity of the oxide semiconductor thin-film transistor resulted from the IGZO encountering vapor, oxygen, etching solution, and the ultraviolet light.

According to an embodiment, the present invention provides a thin-film transistor disposed on a substrate. The thin-film transistor includes a gate, a first insulating layer, a metal-oxide semiconductor pattern, a source and a drain, and a second insulating layer. The gate is disposed on the substrate, and the first insulating layer covers the gate. The metal-oxide semiconductor pattern is disposed on the substrate. The source and the drain are disposed on the first insulating layer. The second insulating layer covers the metal-oxide semiconductor pattern.

According to another embodiment, the present invention further provides an active matrix display panel including a first substrate, a second substrate, a gate, a first insulating layer, a metal-oxide semiconductor pattern, a source, a drain, and a second insulating layer. The second substrate is disposed opposite to the first substrate. The gate is disposed between the first substrate and the second substrate. The first insulating layer is disposed between the gate and the first substrate. The metal-oxide semiconductor pattern is disposed between the first substrate and the second substrate. The source and the drain are disposed between the first insulating layer and the first substrate. The second insulating layer is disposed between the metal-oxide semiconductor pattern and the first substrate.

According to another embodiment, the present invention provides a method of manufacturing a thin-film transistor. First, a gate is formed on a substrate. Next, a first insulating layer is formed to cover the gate, and a metal-oxide semiconductor pattern, a source, and a drain are formed on the first insulating layer. Then, a second insulating layer is formed to cover the metal-oxide semiconductor pattern, the source, and the drain.

The thin-film transistor of the present invention having the second insulating layer covering the oxide semiconductor pattern not only can shield the oxide semiconductor pattern from being illuminated by the ultraviolet light, but also make the electricity of the oxide semiconductor pattern return to be stable through the oxide semiconductor pattern so as to avoid the thin-film transistor from having bad electricity.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 through FIG. 5 are schematic diagrams illustrating a method of manufacturing a thin-film transistor according to a first embodiment of the present invention.

FIG. 6 is a schematic diagram illustrating a relation between photon energy and wavelength.

FIG. 7 is a schematic diagram illustrating a relation between a transmittance of the second insulating layer and a wavelength of a light illuminating on the second insulating layer.

FIG. 8 through FIG. 10 are schematic diagrams illustrating a method of manufacturing a thin-film transistor according to a second embodiment of the present invention.

FIG. 11 and FIG. 12 are schematic diagrams illustrating a method of manufacturing a thin-film transistor according to another example of the second embodiment of the present invention.

FIG. 13 and FIG. 14 are schematic diagrams illustrating a method of manufacturing a thin-film transistor according to a third embodiment of the present invention, wherein FIG. 14 is a schematic diagram illustrating a cross-sectional view of the thin-film transistor according the third embodiment of the present invention.

FIG. 15 is a schematic diagram illustrating a relation between a drain current and a gate voltage of the thin-film transistor whose etching stop pattern is single layer structure and a relation between a drain current and a gate voltage of the thin-film transistor whose etching stop pattern is double layer structure.

FIG. 16 is a schematic diagram illustrating relations between drain current and the gate voltage of the thin-film transistor under the conditions of the passivation layer being composed of silicon oxide or silicon nitride, the passivation layer being second insulating layer, and the channel region being formed by the amorphous silicon.

FIG. 17 is a schematic diagram illustrating a cross-sectional view of a thin-film transistor according a fourth embodiment of the present invention.

FIG. 18 is a schematic diagram illustrating a cross-sectional view of a thin-film transistor according to a fifth embodiment of the present invention.

FIG. 19 is a schematic diagram illustrating a cross-section view of an active matrix display panel according to an embodiment of the present invention.

FIG. 20 is a schematic diagram illustrating a cross-sectional view of an active matrix display panel according to another embodiment of the present invention.

### DETAILED DESCRIPTION

To provide a better understanding of the present invention, embodiments will be detailed as follows. The embodiments of the present invention are illustrated in the accompanying drawings with numbered elements to elaborate the contents and effects to be achieved.

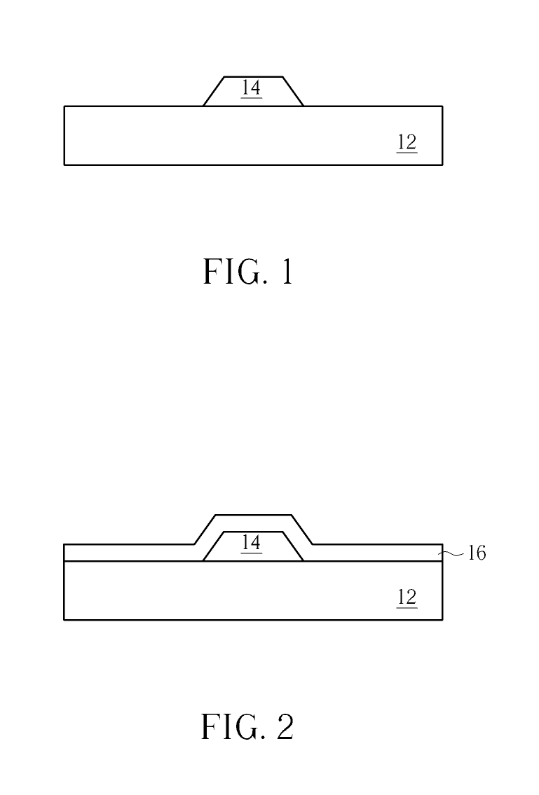

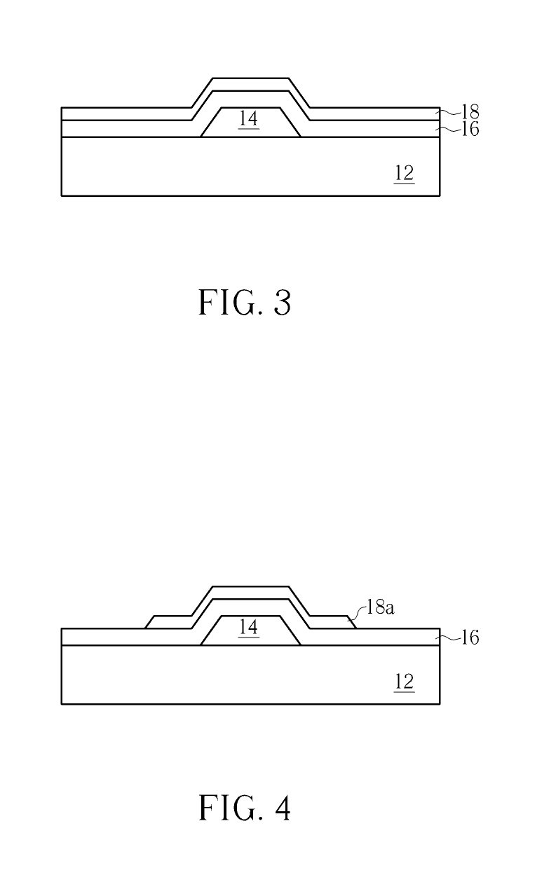

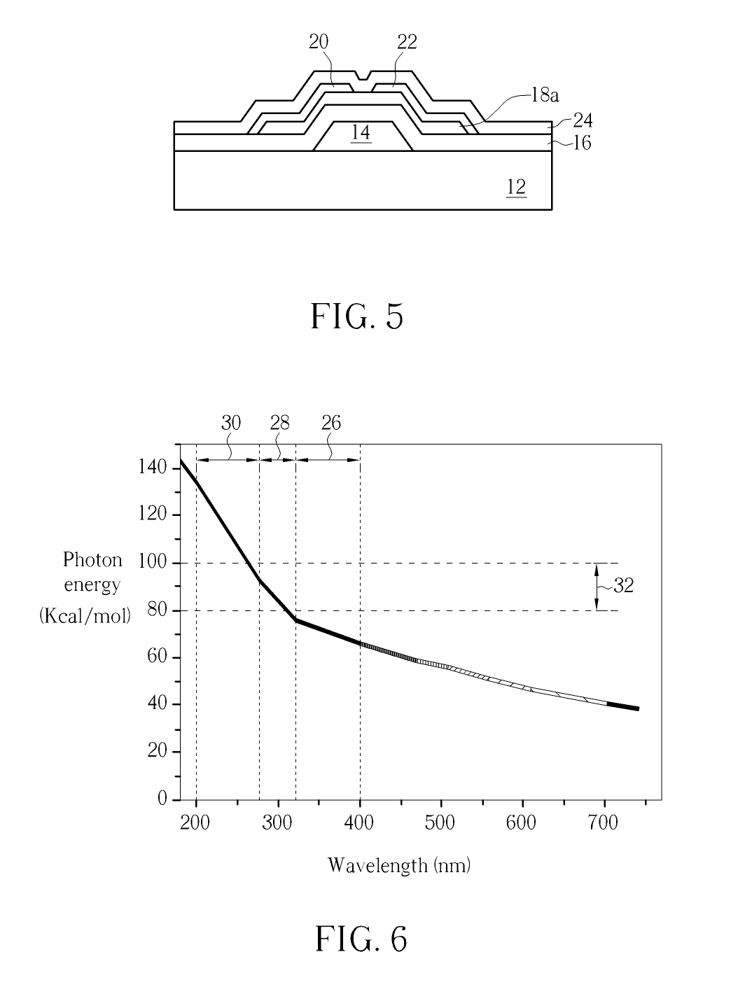

Refer to FIG. 1 through FIG. 5, which are schematic diagrams illustrating a method of manufacturing a thin-film transistor according to a first embodiment of the present invention. FIG. 5 is a schematic diagram illustrating a cross-sectional view of the thin-film transistor according the first embodiment of the present invention. As shown in FIG. 1, a first metal layer is first formed on a substrate 12, and then, a photolithographic process and an etching process are performed to pattern the first metal layer so as to form a gate 14. Next, as shown in FIG. 2, a first insulating layer 16 is formed to cover the gate 14. As shown in FIG. 3, a metal-oxide semiconductor layer 18 is subsequently formed on the first insulating layer 16. In this embodiment, the substrate 12 can be a transparent substrate, such as glass substrate or plastic substrate, but the present invention is not limited herein. In addition, the first insulating layer 16 serves as a gate insulating layer of the thin-film transistor, and can include silicon oxide, silicon nitride or silicon oxynitride, but the present invention is not limited herein. Furthermore, the metal-oxide semiconductor layer 18 includes indium gallium zinc oxide (IGZO).

As shown in FIG. 4, another photolithographic process and another etching process are performed to pattern the metal-oxide semiconductor layer 18 to form a metal-oxide semiconductor pattern 18a, and the metal-oxide semiconductor pattern 18a that is disposed right on the gate 14 serves as a channel region of the thin-film transistor. As shown in FIG. 5, a second metal layer is then formed to cover the first insulating layer 16 and the metal-oxide semiconductor pattern 18a. Afterward, another photolithographic process and another etching process are performed to pattern the second metal layer so as to form a source 20 and a drain 22 on the metal-oxide semiconductor pattern 18a, and the source 20 and the drain 22 partially overlap the gate 14. Finally, a second insulating layer 24 is formed to cover the metal-oxide semiconductor pattern 24, the source 20, and the drain 22 and contact the metal-oxide semiconductor pattern 24. Accordingly, the thin-film transistor 10 of this embodiment is completed. The second insulating layer 24 may includes an insulating polymer layer. Preferably, the insulating polymer layer is selected from polyolefin, polyester, polyacrylate, polyamide and polyimide. For example, when the second insulating layer 24 includes polyimide, the step of forming the second insulating layer 24 may includes the following steps. First, a polyamic acid solution is coated on the metal-oxide semiconductor pattern 18a, the source 20, the drain 22 and the insulating layer 16, and then, a heating step is performed to generate a crosslinking reaction in the polyamic acid solution so as to form a second insulating layer 24.

It should be noted that the polyamic acid solution that is liquid can have good step coverage on the metal-oxide semiconductor pattern 18a, the source 20, the drain 22 and the insulating layer 16, so that the formed second insulating layer 24 can serve as a planar layer, and be avoided from having worse coverage resulted from being manufactured by deposition process on vertical sidewall. Also, the problem of crack at corner due to worse coverage can be solved accordingly. Furthermore, the second insulating layer 24 can filter the ultraviolet light with a wavelength less than 315 nanometers, so that the second insulating layer 24 can further be a protection layer to shield the metal-oxide semiconductor pattern 18a from being illuminated by the ultraviolet light, and the thin-film transistor 10 can be avoided from having bad electricity.

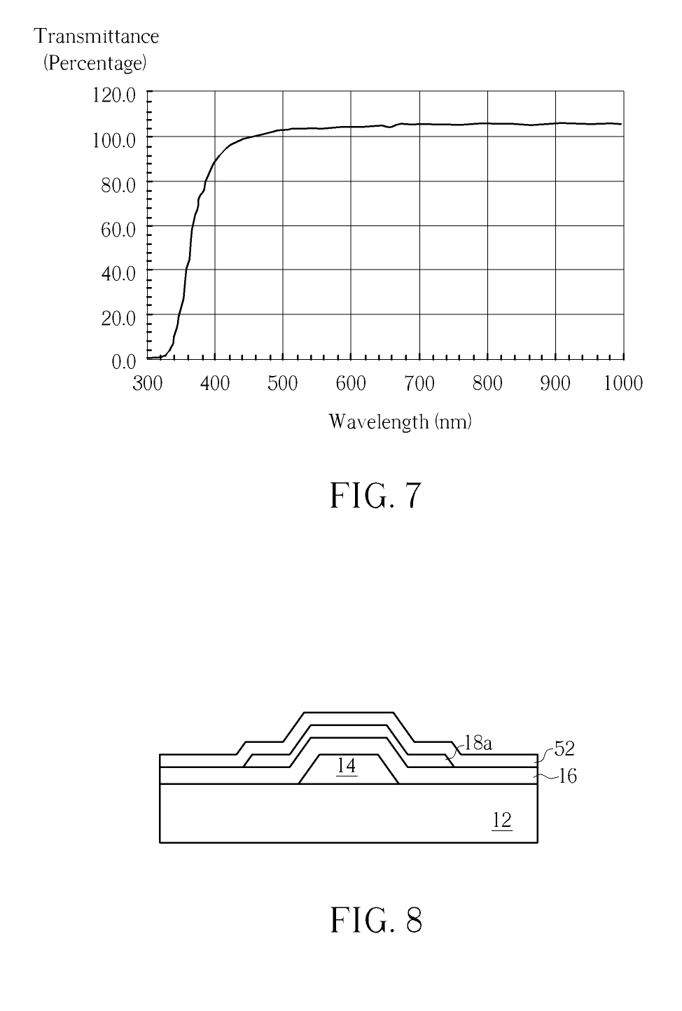

The advantage of the thin-film transistor 10 in this embodiment is further detailed in the following description. Refer to FIG. 6 and FIG. 7 together with FIG. 5. FIG. 6 is a schematic diagram illustrating a relation between photon energy and wavelength, and FIG. 7 is a schematic diagram illustrating a relation between a transmittance of the second insulating layer and a wavelength of a light illuminating on the second insulating layer. As shown in FIG. 6, the spectrum of the ultraviolet light can be divided into a first region 26 called UV-A, a second region 28 called UV-B, and a third region 30 called UV-C. Wavelength ranges of the first region 26, the second region 28, and the third region 30 are respectively 315-400 nm, 280-315 nm, and 100-280 nm. Thus, the photon energy of UV-A is less than the photon energy of UV-B, and the photon energy of UV-B is less than the photon energy of UV-C. It should be noted that the strength range 32 of chemical bonding is between 80 kcal/mol and 100 kcal/mol. Thus, the photon energy of UV-A is not enough to break chemical bonding. As shown in FIG. 7, when the light illuminating on the second insulating layer has a wavelength less than 315 nm, the transmittance is substantially zero, which means the second insulating layer can effectively stop the light with the wavelength less than 315 nm. Accordingly, the second insulating layer can effectively stop UV-B and UV-C that can damage the chemical bonding. In this embodiment, the second insulating layer covering the metal-oxide semiconductor pattern can effectively avoid the metal-oxide semiconductor pattern from being damaged by the UV light from the top of the metal-oxide semiconductor pattern, and the problem of the thin-film transistor having bad electricity due to the UV light can be solved.

In addition, the polymer, such as polyimide molecules, in the second insulating layer have function groups with a carbon-oxygen double bond, so that the oxygen atom can adsorb the hydrogen atom in the metal-oxide semiconductor pattern to form hydrogen bond. Since the metal-oxide semiconductor pattern will be reacted with vapor during the process of manufacturing the same, the number of the hydrogen in the metal-oxide semiconductor pattern is over large, and the electricity of the metal-oxide semiconductor pattern is unstable. Furthermore, the second insulating layer can adsorb the hydrogen atom, so that the electricity of the metal-oxide semiconductor pattern can return to be stable. As a result, the second insulating layer is disposed to be in contact with the metal-oxide semiconductor pattern in this embodiment, so that the metal-oxide semiconductor pattern can return to be stable, and the electricity of the thin-film transistor can be avoided from being affected by vapor. Moreover, when the second insulating layer is disposed at a temperature of 25° C. for 24 hours, the second insulating layer has a water absorption is substantially 0.5%, and the size thereof don't change. Thus, the second insulating layer not only has small line expansion coefficient and size stability, but also can stop vapor from entering into the metal-oxide semiconductor pattern so as to avoid the characteristic of the metal-oxide semiconductor pattern from being affected by vapor. The second insulating layer further has good medicine resistance, good electrical insulation, and low dielectric constant, and can be used under an environment having a temperature of 250-300° C. for a long time. The second insulating layer also has a heat resistant temperature over 400° C., and even higher than 500° C. Thus, the usage range of the thin-film transistor in this embodiment can be effectively raised.

The thin-film transistor of the present invention is not limited to the above-mentioned embodiment. The following description continues to detail the other embodiments or modifications, and in order to simplify and show the difference between the other embodiments or modifications and the above-mentioned embodiment, the same numerals denote the same components in the following description, and the same parts are not detailed redundantly.

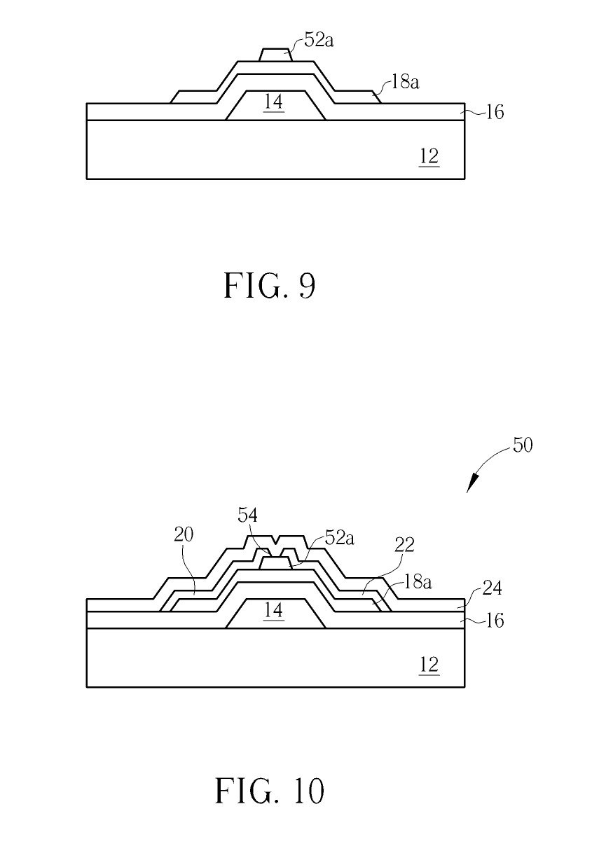

Please refer to FIG. 8 through FIG. 10 together with FIG. 1 through FIG. 4. FIG. 8 through FIG. 10 are schematic diagrams illustrating a method of manufacturing a thin-film transistor according to a second embodiment of the present invention, wherein FIG. 10 is a schematic diagram illustrating a cross-sectional view of the thin-film transistor according the second embodiment of the present invention. As shown in FIG. 1 through FIG. 4, in comparison with the first embodiment, the steps of forming the gate 14, the first insulating layer 16 and the metal-oxide semiconductor pattern 18a on the substrate 12 in this embodiment is the same as the steps in the first embodiment. Then, as shown in FIG. 8, a deposition process, such as physical vapor deposition process or chemical vapor deposition process, is performed to form an etching stop layer 52, such as silicon dioxide, to cover the insulating layer 16 and the metal-oxide semiconductor pattern 18a. Next, as shown in FIG. 9, another photolithographic process and another etching process are performed to pattern the etching stop layer 52 to form an etching stop pattern 52a right on the gate 14. That is, the etching stop pattern 52a is disposed on the metal-oxide semiconductor pattern 18a regarded as the channel region. After that, as shown in FIG. 10, a second metal layer is formed to cover the first insulating layer 16, the metal-oxide semiconductor pattern 18a and the etching stop pattern 52a. Another photolithographic process and another etching process are performed to pattern the second metal layer, so that the source 20 and the drain 22 are formed on the metal-oxide semiconductor pattern 18a and the etching stop pattern 52a. Finally, the second insulating layer 24 is formed on the etching stop pattern 52a, the source 20, the drain 22 and the insulating layer 16, and the thin-film transistor 50 of this embodiment is accordingly completed. It should be noted that the etching stop pattern 52a is formed before forming the source 20 and the drain 22 in the manufacturing method of this embodiment, so that the etching stop pattern 52a can protect the metal-oxide semiconductor pattern 18a regarded as the channel region from being damaged by the etching solution during patterning the second metal layer.

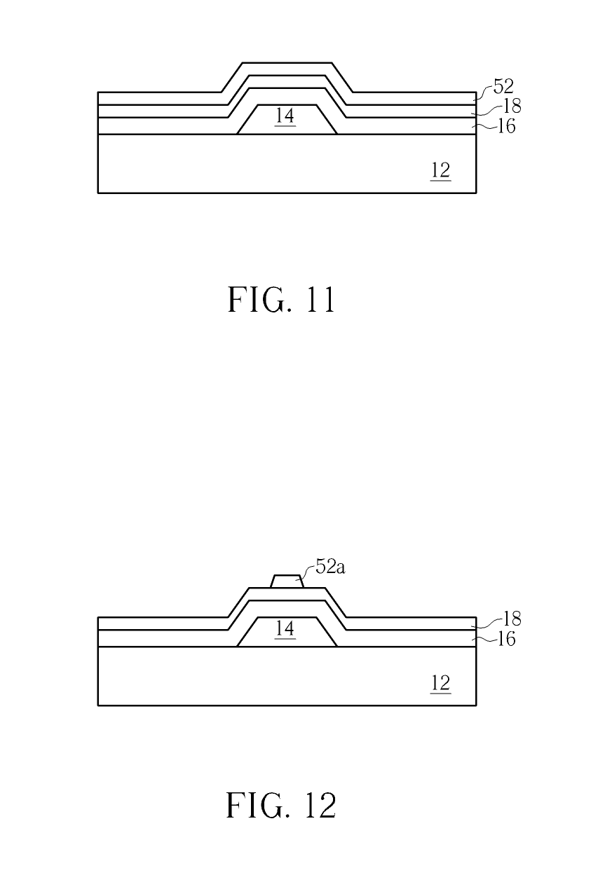

The method of manufacturing the thin-film transistor of this embodiment is not limited to the above-mentioned description. Please refer to FIG. 11 and FIG. 12 together with FIG. 1 through FIG. 3 and FIG. 9 through FIG. 10. FIG. 11 and FIG. 12 are schematic diagrams illustrating a method of manufacturing a thin-film transistor according to another example of the second embodiment of the present invention. The difference between this example and the above-mentioned second embodiment is that the metal-oxide semiconductor layer 18 is not patterned immediately after forming the metal-oxide semiconductor layer 18. The metal-oxide semiconductor layer 18 is patterned after sequentially depositing the etching stop layer 52 and forming the etching stop pattern 52a. As shown in FIG. 11, a deposition process is performed to form an etching stop layer 52 to cover the metal-oxide semiconductor layer 18 after forming the gate 14, the first insulating layer 16 and the metal-oxide semiconductor layer 18 on the substrate 12 by utilizing the steps shown in FIG. 1 through FIG. 3. Thereafter, as shown in FIG. 12, another photolithographic process and another etching process are performed to pattern the etching stop layer 52 to form the etching stop pattern 52a. Then, as shown in FIG. 9, another photolithographic process and another etching process are performed to pattern the metal-oxide semiconductor layer 18 to form an metal-oxide semiconductor pattern 18a. The following steps of this example are the same as the steps shown in FIG. 10 of the above-mentioned second embodiment, and will not be detailed redundantly.

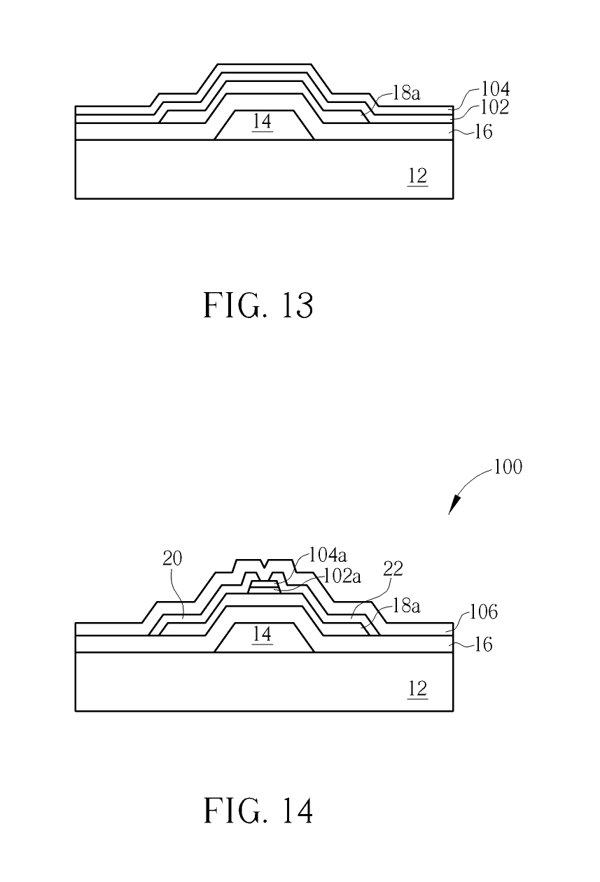

The etching stop layer of the present invention also can have multilayer structure, and the multilayer can be formed by different process conditions respectively to reduce the damage to the metal-oxide semiconductor pattern. Please refer to FIG. 13 and FIG. 14 together with FIG. 1 through FIG. 4. FIG. 13 and FIG. 14 are schematic diagrams illustrating a method of manufacturing a thin-film transistor according to a third embodiment of the present invention, wherein FIG. 14 is a schematic diagram illustrating a cross-sectional view of the thin-film transistor according the third embodiment of the present invention. As shown in FIG. 1 through FIG. 4, as compared with second embodiment, the steps of forming the gate 14, the first insulating layer 16 and the metal-oxide semiconductor pattern 18a on the substrate 12 in this embodiment are the same as that in the second embodiment. After that, as shown in FIG. 13, a physical vapor deposition process is performed to form a second etching stop layer 102, such as silicon dioxide, to cover the metal-oxide semiconductor pattern 18a and the first insulating layer 16. Subsequently, a chemical vapor deposition process is performed to form a first etching stop layer 104, such as silicon dioxide, to cover the second etching stop layer 102. Then, as shown in FIG. 14, another photolithographic process and another etching process are performed to pattern the first etching stop layer 104 and the second etching stop layer 102, and the first etching stop pattern 104a and the second etching stop pattern 102a are accordingly formed. The second etching stop pattern 102a and the first etching stop pattern are sequentially stacked on the oxide semiconductor patter 18a. Later, a second metal layer is formed to cover the first insulating layer 16, the metal-oxide semiconductor pattern 18a and the first etching stop patter 104a. Another photolithographic process and another etching process are performed to pattern the second metal layer to form the source 20 and the drain 22 on the metal-oxide semiconductor pattern 18a and the first etching stop pattern 104a and to form the opening 54 between the source 20 and the drain 22 that exposes the first etching stop pattern 104a. Finally, a passivation layer 106 is formed on the first etching stop patter 104a, the source 20, the drain 22 and the first insulating layer 16, and the thin-film transistor of this embodiment is accordingly completed.

In this embodiment, the physical vapor deposition process is a sputtering process, which utilizes silicon oxide as a target material and argon ions to bomb the target material, thereby depositing the silicon oxide on the metal-oxide semiconductor pattern 18a and forming the second etching stop layer 102. The physical vapor deposition process of the present invention is not limited to be the sputtering process, and the target material of the second etching material is not limited to be silicon oxide. The chemical vapor deposition process of this embodiment can be a plasma-enhanced chemical vapor deposition (PECVD) process, but is not limited herein. It should be noted that the physical vapor deposition process for forming the second etching stop layer 102 utilizes low power lower than the power of the chemical vapor deposition process, so that the damage of the argon ions to the metal-oxide semiconductor pattern 18a in the physical vapor deposition process can be reduced, and the damage to the metal-oxide semiconductor pattern 18a in the following chemical vapor deposition process can also be reduced. The first etching stop pattern 104a has a first thin-film density, and the second etching stop pattern 102a has a second thin-film density lower than the first thin-film density. In addition, the chemical vapor deposition process utilizes high power to form the first etching stop pattern 104a, and the first etching stop pattern 104a having the first thin-film density can be used to protect the metal-oxide semiconductor pattern 18a regarded as the channel region. Furthermore, the passivation layer 106 of this embodiment may include an insulating polymer layer. Preferably, the insulating polymer layer is selected from polyolefin, polyester, polyacrylate, polyamide and polyimide, but is not limited to this. The passivation layer of the present invention also can be composed of insulating material, such as silicon oxide or silicon nitride. The etching stop pattern of the present invention is not limited to be formed by the first etching stop pattern and the second etching stop pattern, and also can be formed by a plurality of etching stop patterns.

In other embodiments of the present invention, the metal-oxide semiconductor layer is not patterned immediately after forming the metal-oxide semiconductor layer. The physical vapor deposition process and the chemical vapor deposition process are sequentially performed to deposit the second etching stop layer and the first etching stop layer in order on the metal-oxide semiconductor layer after forming the metal-oxide semiconductor layer. The first etching stop pattern and the second etching stop pattern are then formed, and the metal-oxide semiconductor layer is patterned.

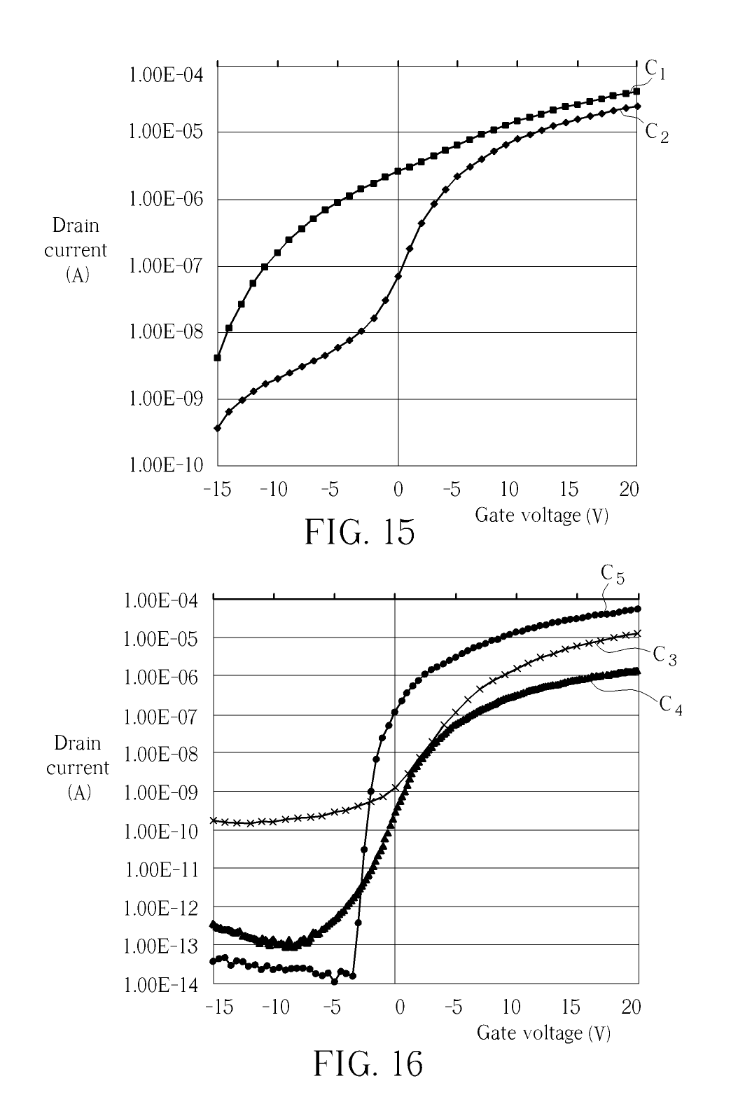

The following description will further mention the advantage of the thin-film transistor of the third embodiment. Please refer to FIG. 15, which is a schematic diagram illustrating a relation between a drain current and a gate voltage of the thin-film transistor whose etching stop pattern is single layer structure and a relation between a drain current and a gate voltage of the thin-film transistor whose etching stop pattern is double layer structure. As shown in FIG. 15, a first curve C1 represents a relation curve between the drain current and the gate voltage of the thin-film transistor when the etching stop pattern of the thin-film transistor is single layer structure, and the passivation layer is composed of silicon oxide or silicon nitride. A second curve C2 represents a relation curve between the drain current and the gate voltage of the thin-film transistor when the etching stop pattern of the thin-film transistor is single layer structure, and the passivation layer is composed of silicon oxide or silicon nitride. A subthreshold swing of the first curve C1, which is a reciprocal of a slope of the first curve C1, is larger than a subthreshold swing of the second curve C2. As we can know from the above-mentioned description, the method of manufacturing the thin-film transistor of the third embodiment uses the physical vapor deposition process with lower power to form the second etching stop pattern and uses the chemical vapor deposition process with higher power to form the first etching stop pattern with higher thin-film density, so that the subthreshold swing of the thin-film transistor can be decreased, and the switching characteristic of the thin-film transistor can be highlighted. Please refer to FIG. 16, which is a schematic diagram illustrating relations between drain current and the gate voltage of the thin-film transistor under the conditions of the passivation layer being composed of silicon oxide or silicon nitride, the passivation layer being formed with insulating polymer, and the channel region being formed by the amorphous silicon. As shown in FIG. 16, a third curve C3 represents a relation curve between the drain current and the gate voltage of the thin-film transistor according to the above-mentioned third embodiment whose passivation layer is composed of silicon oxide or silicon nitride. A fourth curve C4 represents a relation curve between the drain current and the gate voltage of the thin-film transistor according to the above-mentioned third embodiment whose channel region is formed by the amorphous silicon. A fifth curve C5 represents a relation curve between the drain current and the gate voltage of the thin-film transistor according to the above-mentioned third embodiment whose passivation layer is formed with insulating polymer. Since the subthreshold swing of the third curve C3 is larger than the subthreshold swing of the fifth curve C5, the switching characteristic of the thin-film transistor whose passivation layer is formed with insulating polymer is preferable to the switching characteristic of the thin-film transistor whose passivation layer is composed of silicon oxide or silicon nitride. Furthermore, the subthreshold swing of the third curve C4 is larger than the subthreshold swing of the fifth curve C5, so the switching characteristic of the thin-film transistor whose passivation layer is formed with insulating polymer is more preferable to the switching characteristic of the thin-film transistor whose channel region is composed of amorphous silicon.

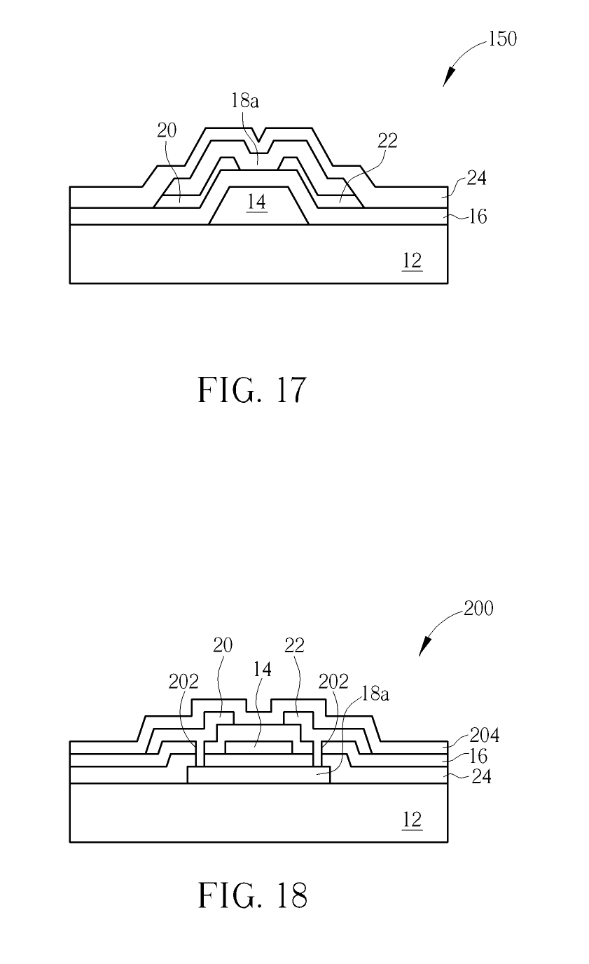

Please refer to FIG. 17, which is a schematic diagram illustrating a cross-sectional view of a thin-film transistor according a fourth embodiment of the present invention. As shown in FIG. 17, as compared with the first embodiment, the step of forming the metal-oxide semiconductor pattern 18a in this embodiment is performed between the step of forming the source 20 and the drain 22 and the step of forming the second insulating layer 24. Accordingly, the metal-oxide semiconductor pattern 18a of the thin-film transistor 150 in this embodiment is disposed between the source 20 and the second insulating layer 24 and between the drain 22 and the second insulating layer 24, and extends into the opening between the source 20 and the drain 22 to be in contact with the insulating layer 16.

Please refer to FIG. 18, which is a schematic diagram illustrating a cross-sectional view of a thin-film transistor according to a fifth embodiment of the present invention. As compared with the first embodiment, the thin-film transistor of this embodiment is a top gate type thin-film transistor. As shown in FIG. 18, the metal-oxide semiconductor pattern 18a is formed first on the substrate 12 in this embodiment. Then, the second insulating layer 24 is formed to cover the oxide semiconductor patter 18a and the substrate 12. The gate 14 is formed on the second insulating layer 24, and the first insulating layer 16 is formed to cover the gate 14 and the second insulating layer 24. After that, two through holes 202 are formed respectively in the first insulating layer 16 and the second insulating layer 24 at two sides of the gate 14, and each through hole 202 penetrates through the first insulating layer 16 and the second insulating layer 24 and exposes the metal-oxide semiconductor pattern 18a. Following that, the source 20 and the drain 22 are formed on the first insulating layer 16 and fill into the through hole 202 respectively. The source 20 and the drain 22 can be in contact with the metal-oxide semiconductor pattern 18a respectively through the through holes 202. Subsequently, a passivation layer 204 is formed to cover the source 20, the drain 22 and the first insulating layer 16, and the thin-film transistor 200 of this embodiment is accordingly completed.

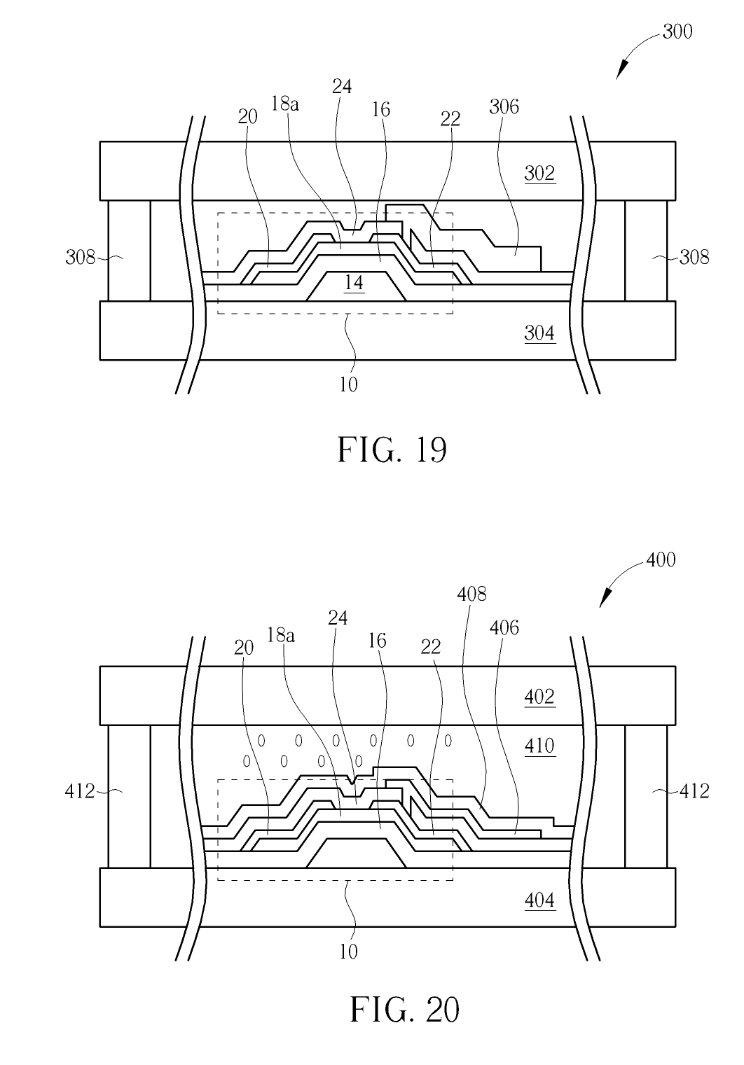

The present invention further provides an active matrix display panel using the thin-film transistor according to any above-mentioned embodiment. Please refer to FIG. 19 and FIG. 20. FIG. 19 is a schematic diagram illustrating a cross-section view of an active matrix display panel according to an embodiment of the present invention, and FIG. 20 is a schematic diagram illustrating a cross-sectional view of an active matrix display panel according to another embodiment of the present invention. The following description takes the thin-film transistor of the above-mentioned first embodiment as an example, but is not limited herein. The structure of the thin-film transistor will not be detailed redundantly. As shown in FIG. 19, the active matrix display panel 300 is an organic electroluminescent display panel, which includes a first substrate 302, a second substrate 304, a thin-film transistor 10, an organic electroluminescent unit 306, and a sealant 308 in this embodiment. The first substrate 302 and the second substrate 304 are disposed opposite to each other, and the thin-film transistor 10 disposed on the second substrate 304 between the first substrate 302 and the second substrate 304. The organic electroluminescent unit 306 is disposed between the second insulating layer 24 of the thin-film transistor 10 and the first substrate 302, and can be composed of an anode, an organic electroluminescent layer and a cathode, but is not limited to this. The sealant 308 is disposed between the first substrate 302 and the second substrate 304, and is configured to stick the first substrate 302 to the second substrate 304. The sealant 308 does not overlap the second insulating layer 24, so that the sealant 308 peeling off from the second insulating layer 24 due to insufficient adhesion between the sealant 308 and the second insulating layer 24 can be avoided. As shown in FIG. 20, as compared with the above-mentioned embodiment, the active matrix display panel 400 is a liquid crystal display panel, which includes a first substrate 402, a second substrate 404, a thin-film transistor 10, a pixel electrode layer 406, an alignment layer 408, a liquid crystal layer 410, and a sealant 412 in this embodiment. The first substrate 402 can be color filter substrate in this embodiment, but is not limited to this. The first substrate 402 and the second substrate 404 are disposed opposite to each other, and the liquid crystal layer 410 is disposed between the first substrate 402 and the second substrate 404. The thin-film transistor 10 is disposed on the second substrate 404 between the first substrate 402 and the second substrate 404. The pixel electrode layer 406 is disposed between the second insulating layer 24 of the thin-film transistor 10 and the liquid crystal layer 410, and the alignment layer 408 is disposed between the second insulating layer 24 of the thin-film transistor 10 and the liquid crystal layer 410 and between the pixel electrode layer 406 and the liquid crystal layer 410. The sealant 412 is disposed between the first substrate 402 and the second substrate 404, and is configured to stick the first substrate 402 to the second substrate 404. The sealant 408 does not overlap the second insulating layer 24. The active matrix display panel of the present invention is not limited to the above-mentioned embodiments, and can be other kinds of display panels.

In summary, the thin-film transistor of the present invention having the second insulating layer including insulating polymer and covering the metal-oxide semiconductor pattern not only can shield the metal-oxide semiconductor pattern from being illuminated by the ultraviolet light, but also make the electricity of the metal-oxide semiconductor pattern return to be stable through the metal-oxide semiconductor pattern so as to avoid the thin-film transistor from having bad electricity. Additionally, the thin-film transistor of the present invention further has the second etching stop pattern formed on the metal-oxide semiconductor pattern through the deposition process with low power, and has the first etching top pattern formed on the second etching stop pattern through the deposition process with high power. Thus, the damage of the argon ions to the metal-oxide semiconductor pattern in the deposition process can be reduced, and the first etching stop pattern can be used to protect the metal-oxide semiconductor pattern serving as channel region. Also, the switching characteristic of the thin-film transistor can be efficiently improved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A thin-film transistor disposed on a substrate, and the thin-film transistor comprising:
a gate disposed on the substrate;
a first insulating layer covering the gate;
a metal-oxide semiconductor pattern disposed on the substrate;
a source and a drain disposed on the first insulating layer; and
a second insulating layer covering the metal-oxide semiconductor pattern.

2. The thin-film transistor according to claim 1, wherein the metal-oxide semiconductor pattern comprises indium gallium zinc oxide (IGZO).

3. The thin-film transistor according to claim 1, wherein the metal-oxide semiconductor pattern is disposed between the first insulating layer and the source and between the first insulating layer and the drain.

4. The thin-film transistor according to claim 3, further comprising a first etching stop pattern disposed between the second insulating layer and the metal-oxide semiconductor pattern, and the first etching stop pattern having a first thin-film density.

5. The thin-film transistor according to claim 4, further comprising a second etching stop pattern disposed between the first etching stop pattern and the metal-oxide semiconductor pattern, and the second etching stop pattern having a second thin-film density less than the first thin-film density.

6. The thin-film transistor according to claim 1, wherein the metal-oxide semiconductor pattern is disposed between the source and the second insulating layer and between the drain and the second insulating layer, and extends to be disposed between the source and the drain.

7. The thin-film transistor according to claim 1, wherein the gate is disposed on the second insulating layer.

8. The thin-film transistor according to claim 7, wherein the first insulating layer and the second insulating layer have two through holes, and the source and the drain are in contact with the metal-oxide semiconductor pattern respectively via the through holes.

9. The thin-film transistor according to claim 1, wherein the second insulating layer is a protection layer.

10. The thin-film transistor according to claim 1, wherein the second insulating layer includes an insulating polymer layer.

11. The thin-film transistor according to claim 10, wherein the insulating polymer layer is selected from polyolefin, polyester, polyacrylate, polyamide and polyimide.

12. An active matrix display panel, comprising:
a first substrate;
a second substrate disposed opposite to the first substrate;
a gate disposed between the first substrate and the second substrate;
a first insulating layer disposed between the gate and the first substrate;
a metal-oxide semiconductor pattern disposed between the first substrate and the second substrate;
a source and a drain disposed between the first insulating layer and the first substrate; and
a second insulating layer disposed between the metal-oxide semiconductor pattern and the first substrate.

13. The active matrix display panel according to claim 12, further comprising:
a liquid crystal layer disposed between the first substrate and the second substrate;
a pixel electrode layer disposed between the second insulating layer and the liquid crystal layer; and
an alignment layer disposed between the pixel electrode layer and the liquid crystal layer.

14. The active matrix display panel according to claim 12, further comprising an organic electroluminescent unit disposed between the second insulating layer and the first substrate.

15. The active matrix display panel according to claim 12, wherein the metal-oxide semiconductor pattern comprises IGZO.

16. The active matrix display panel according to claim 12, wherein the metal-oxide semiconductor pattern is disposed between the first insulating layer and the source and between the first insulating layer and the drain.

17. The active matrix display panel according to claim 16, further comprising a first etching stop pattern disposed between the second insulating layer and the metal-oxide semiconductor pattern, and the first etching stop pattern having a first thin-film density.

18. The active matrix display panel according to claim 17, further comprising a second etching stop pattern disposed between the first etching stop pattern and the metal-oxide semiconductor pattern, and the second etching stop pattern having a second thin-film density less than the first thin-film density.

19. The active matrix display panel according to claim 12, wherein the metal-oxide semiconductor pattern is disposed between the source and the second insulating layer and between the drain and the second insulating layer, and extends to be disposed between the source and the drain.

20. The active matrix display panel according to claim 12, wherein the gate is disposed between the second insulating layer and the first substrate.

21. The active matrix display panel according to claim 20, wherein the first insulating layer and the second insulating layer have two through holes, and the source and the drain are in contact with the metal-oxide semiconductor pattern respectively via the through holes.

22. The active matrix display panel according to claim 12, further comprising a sealant disposed between the first substrate and the second substrate and configured to stick the first substrate to the second substrate, and the sealant being not overlapped with the second insulating layer.

23. The active matrix display panel according to claim 12, wherein the second insulating layer is a protection layer.

24. The active matrix display panel according to claim 12, wherein the second insulating layer includes an insulating polymer layer.

25. The thin-film transistor according to claim 24, wherein the insulating polymer layer is selected from polyolefin, polyester, polyacrylate, polyamide and polyimide.

26. A method of manufacturing a thin-film transistor, comprising:
forming a gate on a substrate;
forming a first insulating layer to cover the gate;
forming a metal-oxide semiconductor pattern, a source, and a drain on the first insulating layer; and
forming a second insulating layer to cover the metal-oxide semiconductor pattern, the source, and the drain.

27. The method of manufacturing a thin-film transistor according to claim 26, wherein the step of forming the metal-oxide semiconductor pattern, the source, and the drain comprises:
forming the metal-oxide semiconductor pattern on the first insulating layer; and
forming the source and the drain on the metal-oxide semiconductor pattern.

28. The method of manufacturing a thin-film transistor according to claim 27, wherein between the step of forming the metal-oxide semiconductor pattern and the step of forming the source and the drain, the method further comprises forming a first etching stop pattern on the metal-oxide semiconductor pattern.

29. The method of manufacturing a thin-film transistor according to claim 28, wherein between the step of forming the metal-oxide semiconductor pattern and the step of forming the source and the drain, the method further comprises forming a second etching stop pattern between the first etching stop pattern and the metal-oxide semiconductor pattern, wherein the first etching stop pattern has a first thin-film density, and the second etching stop pattern has a second thin-film density less than the first thin-film density.

30. The method of manufacturing a thin-film transistor according to claim 29, wherein the step of forming the second etching stop pattern comprises a physical vapor deposition process, and the step of forming the first etching stop pattern comprises a chemical vapor deposition process.

31. The method of manufacturing a thin-film transistor according to claim 28, wherein the step of forming the metal-oxide semiconductor pattern comprises:
forming a metal-oxide semiconductor layer and a first etching stop layer on the first insulating layer in sequence;
patterning the first etching stop layer to form a first etching stop pattern; and
patterning the metal-oxide semiconductor layer to form the metal-oxide semiconductor pattern.

32. The method of manufacturing a thin-film transistor according to claim 26, wherein the step of forming the metal-oxide semiconductor pattern, the source, and the drain comprises:
forming the source and the drain on the first insulating layer; and
forming the metal-oxide semiconductor pattern on the first insulating layer, the source, and the drain.
